(19) United States
(12) Patent Application Publication
(10) Pub. No.: US 2025/0374491 A1
(43) Pub. Date: Dec. 4, 2025

(54) Integrated Metal Heat Spreader For Power Adapter

(71) Applicant: Flex Ltd., Singapore (SG)

(72) Inventors: Yung You LIN, New Taipei City (TW); Hung Cheng CHANG, New Taipei City (TW); Lien Jin CHIANG, New Taipei City (TW)

(73) Assignee: Flex Ltd., Singapore (SG)

(21) Appl. No.: 18/676,184

(22) Filed: May 28, 2024

(51) Int. Cl. H05K 7/20

(52) U.S. Cl. CPC H05K 7/209

(57) ABSTRACT

An integrated heat spreader power adapter includes an integrated heat spreader housing formed by insert molding of a housing and a heat spreader and an internal cavity formed by the integrated heat spreader housing. The integrated heat spreading housing increases a size of the internal cavity. The integrated heat spreader power adapter further includes a printed circuit board assembly provided within the increased size of the internal cavity formed by the integrated heat spreader housing. The printed circuit board is sized based on the increased size of the internal cavity and includes electronic components provided thereon to cause the integrated heat spreader power adapter to be configured to deliver an output power of at least 320 watts. The integrated heat spreader power adapter has a volume of less than 270,000 mm³.

### FIELD

The present disclosure is related generally to the field of power adapters for electronic devices, and more specifically to methods, systems, and devices for improved thermal performance, increased density, and reduced size for power adapters.

### BACKGROUND

A power adapter is sometimes called an alternating current (AC) power adapter or AC adapter. The power adapter serves the purpose of converting AC voltage to a single direct current (DC) voltage for electronic devices, such as, but not limiting to computing devices. The power adapter operates as an external battery, so the computing device's size does not need to be so large. Computing devices use many different DC voltages. One DC voltage is provided by the power adapter and the other DC voltage is provided by internal circuits in the computing device itself. The power adapter serves as the battery that is providing specific energy and voltage to a specific computing device that the power adapter is plugged into.

Conventional power adapters are bulky, heavy, and cumbersome. In addition, conventional power adapters frequently operate at elevated temperatures which results in a reduced life cycle of the conventional power adapter and increased expense associated with replacement costs. The current market trends demand thinner and more lightweight power adapters. Moreover, a smaller form factor at a given power is equivalent to an increase in power density of the power adapter. To achieve a design target having a higher power density (e.g., an enhanced utilization of the inside space of the power adapter), designers reduce the number of component internal to the power adapter, optimize the assembly structure of the power adapter or both. Each of the internal components of the power adapter has its own thickness. Moreover, these internal components are stacked on top of each other. This arrangement of the internal components provided within the power adapter limits component selection and printed circuit board assembly space utilization.

Accordingly, there is a need for an integrated heat spreader power adapter that has improved thermal performance, has increased density, and is lightweight.

### BRIEF DESCRIPTION OF THE DRAWINGS

FIG. 1 is a diagram illustrating a cross-sectional side view of a conventional power adapter;

FIG. 2 is a diagram illustrating a cross-sectional side view of an exemplary integrated heat spreader power adapter according to an embodiment of the present disclosure;

FIG. 3a is a diagram illustrating an isometric view of a conventional power adapter after performance of a thermal simulation;

FIG. 3b is a diagram illustrating an isometric view of an exemplary integrated heat spreader power adapter according to an embodiment of the present disclosure after performance of a thermal simulation;

FIG. 4a is a diagram illustrating an isometric view of the construction of a conventional power adapter;

FIG. 4b is a diagram illustrating an isometric view of the construction of an exemplary integrated heat spreader power adapter according to an embodiment of the present disclosure;

FIG. 5 is a flowchart illustrating an example method for forming an integrated heat spreader power adapter in accordance with embodiments of the present disclosure; and

FIG. 6 is a block diagram of an electronic device system according to an embodiment of the present disclosure.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

Embodiments of the present disclosure are directed to methods, devices and systems for an integrated heat spreader power adapter.

Embodiments of the present disclosure include a method for manufacturing an integrated heat spreader power adapter including integrally forming a heat spreader within inner surfaces of a housing by insert molding to form an integrated heat spreader housing and increasing a size of an internal cavity formed by the integrated heat spreader housing. The method also includes sizing a printed circuit board assembly based on the increased size of the internal cavity formed by the integrated heat spreader housing, providing electronic components on the printed circuit board assembly to cause the integrated heat spreader power adapter to be configured to deliver an output power of a least 320 watts and enclosing the printed circuit board assembly within the internal cavity of the integrated heat spreader housing. The integrated heat spreader power adapter has a volume of less than 270,000 mm³.

Aspects of the above method include wherein the heat spreader of the integrated heat spreader housing comprises a metal.

Aspects of the above method include wherein the housing of the integrated heat spreader housing comprises a plastic material.

Aspects of the above method include wherein a power conversion density of the integrated heat spreader power adapter is 1.1 W/Kg or higher.

Aspects of the above method include providing an insulator between the integrated heat spreader housing and the printed circuit board assembly.

Aspects of the above method include increasing the size of the internal cavity with the integrated heat spreader housing formed by insert molding by at least 15% as compared with a nonintegrated heat spreader housing.

Aspects of the above method include decreasing a thickness of a length of the housing of the integrated heat spreader power adapter formed by insert molding by at least 40% as compared with a nonintegrated heat spreader housing.

Aspects of the above method include decreasing a thickness of a height of the housing of the integrated heat spreader power adapter formed by insert molding by at least 40% as compared with a power adapter formed by a nonintegrated heat spreader housing.

Aspects of the above method include lowering an external surface temperature of the integrated heat spreader power adapter formed with the integrated heat spreader housing as compared with a power adapter formed by a nonintegrated heat spreader housing.

Aspects of the above method include wherein during operation of the integrated heat spreader power adapter, an external surface temperature of a top portion of the integrated heat spreader power adapter is below 75° C.

Aspects of the above method include wherein during operation of the integrated heat spreader power adapter, an external surface temperature of a bottom portion of the integrated heat spreader power adapter is below 78° C.

Aspects of the above method include wherein during operation of the integrated heat spreader power adapter, an external surface temperature of side portions of the power adapter is below 70° C.

Embodiments of the present disclosure include an integrated heat spreader power adapter including an integrated heat spreader housing formed by insert molding of a housing and a heat spreader and an internal cavity formed by the integrated heat spreader housing. The integrated heat spreading housing increases a size of the internal cavity. The integrated heat spreader power adapter further includes a printed circuit board assembly provided within the increased size of the internal cavity formed by the integrated heat spreader housing. The printed circuit board is sized based on the increased size of the internal cavity and includes electronic components provided thereon to cause the integrated heat spreader power adapter to be configured to deliver an output power of at least 320 watts. The integrated heat spreader power adapter has a volume of less than 270,000 mm³.

Aspects of the above integrated heat spreader power adapter include an insulator provided between the integrated heat spreader housing and the printed circuit board assembly.

Aspects of the above integrated heat spreader power adapter include wherein the heat spreader comprises a metal and the housing comprises a plastic material.

Aspects of the above integrated heat spreader power adapter include wherein a power conversion density of the integrated heat spreader power adapter is 1.2 W/Kg or higher.

Aspects of the above integrated heat spreader power adapter of claim 13, wherein during operation of the integrated heat spreader power adapter, an external surface temperature of a top portion of the integrated heat spreader power adapter is below 75° C.

Embodiments of the present disclosure include an electronic device system including an integrated heat spreader power adapter and an electronic device. The integrated heat spreader power adapter includes an integrated heat spreader housing formed by insert molding of a housing and a heat spreader and an internal cavity formed by the integrated heat spreader housing. The integrated heat spreading housing increases a size of the internal cavity. The integrated heat spreader power adapter further includes a printed circuit board assembly provided within the increased size of the internal cavity formed by the integrated heat spreader housing.

The printed circuit board is sized based on the increased size of the internal cavity and includes electronic components provided thereon to cause the integrated heat spreader power adapter to be configured to deliver an output power of at least 320 watts The integrated heat spreader power adapter has a volume of less than 270,000 mm³. The integrated heat spreader power adapter is coupled to charge the electronic device.

Aspects of the above electronic device system include an insulator provided between the integrated heat spreader housing and the printed circuit board assembly.

Aspects of the above electronic device system include wherein the heat spreader comprises a metal and the housing comprises a plastic material.

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides exemplary embodiments only and is not intended to limit the scope or applicability of the disclosure. Furthermore, to avoid unnecessarily obscuring the present disclosure, the preceding description omits a number of known structures and devices. This omission is not to be construed as a limitation of the scope of the claims. Rather, the ensuing description of the exemplary embodiments will provide those skilled in the art with an enabling description for implementing an exemplary embodiment. It should however be appreciated that the present disclosure may be practiced in a variety of ways beyond the specific detail set forth herein.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

Various additional details of embodiments of the present disclosure will be described below with reference to the figures. While the flowcharts will be discussed and illustrated in relation to a particular sequence of events, it should be appreciated that changes, additions, and omissions to this sequence can occur without materially affecting the operation of the disclosed embodiments, configuration, and aspects.

Power adapters for consumer electronic devices tend to be large and heavy. In particular, power adapters for portable electronic devices that draw a larger amount of power (e.g., greater than 40 W), such as laptop computers, for example, are relatively large and heavy. For a mobile device, such as a laptop computer, having a large and heavy power adapter can be particularly cumbersome, as the user may need to carry around such an adapter when the user expects to be away from a power outlet for any significant period of time.

There are several limitations involved with reducing the overall size of power adapters such as the size of the internal space provided within the power adapter, the size of the electronic components used in the power adapter and the heat generated by the electronic components provided within the power adapters. For example, if the electronic components of the power adapter switch frequencies, passive components such as inductors or conductors, need to be prohibitively large to provide a sufficient amount of energy storage during switching intervals. This creates a problem when trying to reduce the overall size of the power adapter with a limited internal space. Moreover, for high frequency switching power adapters, although the size of the passive components can be reduced, the heat generated by the power adapters is a challenge to remove. The smaller a power adapter is made, the more challenging it becomes to remove the heat that is produced by the electronic components. Failing to remove the heat adequately causes a rise in temperature that may reduce component lifetimes and/or cause the temperature of the power adapter to exceed acceptable standards for consumer electronics.

In accordance with some embodiments of the present disclosure, techniques are described herein that enable constructing a power adapter of relatively small size that is able to provide a significant amount of power to one or more electronic devices without overheating.

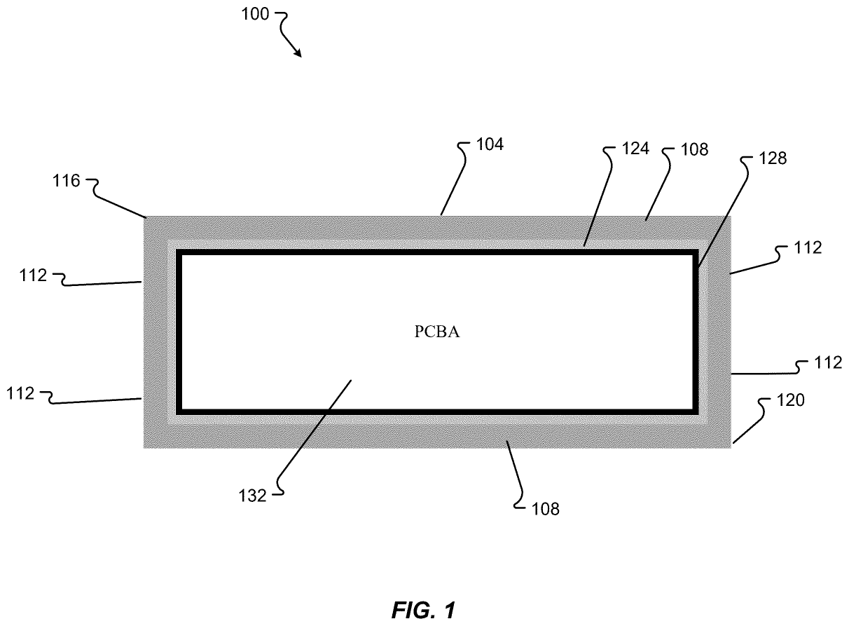

FIG. 1 is a diagram illustrating a cross-sectional side view of a conventional power adapter 100. The power adapter 100 generally includes components such as a housing 104 including a top cover shell 116 and a bottom cover shell 120. Each of the top cover shell 116 and the bottom cover shell 120 include a horizontal portion 108 and vertical portions 112. The top cover shell 116 and the bottom cover shell 120 are secured together such as by electronic welding or by a snap-fit, as are known in the art.

The housing 104 can be made from various materials including, but not limited to electrically insulating materials such as plastics or thermal plastics. The power adapter 100 further includes a heat spreader 124, an insulator 128 and a printed circuit board assembly 132. The heat spreader 124 is made of efficient heat conducting materials including, but not limited to, metals such as aluminum or copper or a metal alloy such as stainless steel. The heat spreader 124 is used to spread the heat from one heat generating component such that the heat is not concentrated in a small area. The insulator 128 can be made from various composite polymer materials.

The printed circuit board assembly 132 is disposed within the housing 104 and includes various electronic components. The various electronic components are assembled onto the printed circuit board assembly 132 using screws, glue or other assembly mechanisms along with a thermal interface. The various electronic components included on the printed circuit board assembly 132 mainly include, for example a transformer, a rectifier, filter capacitors, a voltage regulator, power switching circuitry, a controller, etc.

The printed circuit board assembly 132 may further include a heat sink and a fan wherein the heat sink absorbs heat from the various electronic components and the fan causes current of the air to carry heat from the heat sink to the outside of the housing 104 to lower the inside temperature of the power adapter.

The external dimensions of the conventional power adapter 100 are 95×95×28 millimeter (mm)s. Moreover, the thickness of the horizontal portions 108 is 2.2 mm and the thickness of the vertical portions 112 is 2.7 mm. The heat spreader 124 has a thickness of 1.2 mm. Therefore, the combination of the housing 104 and the heat spreader 124 for the horizontal and vertical portions are 3.4 mm and 3.9 mm, respectively. The insulator 128 has a thickness of 1.25 mm. Therefore, the printed circuit board assembly 132 has a volume or space of 86.7×86.7×20.7 mm or 155,600 mm³. The conventional power adapter 100 has a power output of 300 watts (W). With the conventional power adapter 100, each of the components identified above is assembled separately. With this separate assembly of the components, there is wasted space between the components, and it takes time to separately assemble these components.

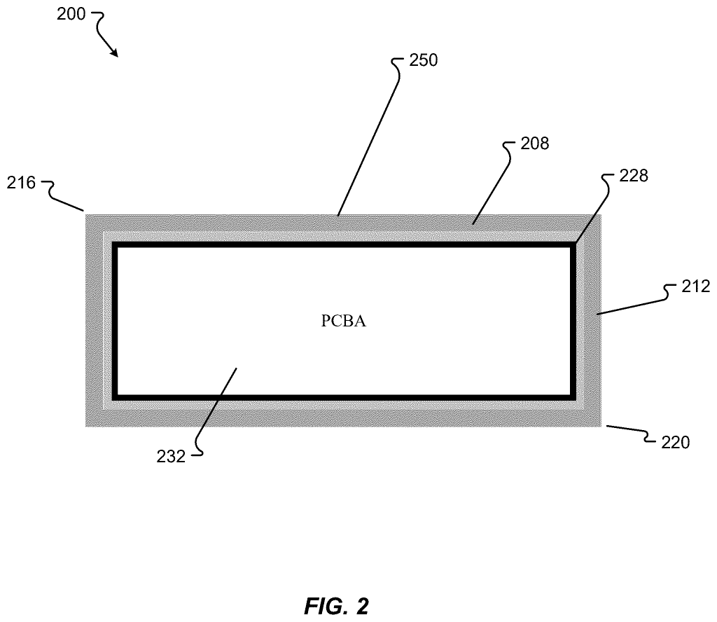

FIG. 2 is a diagram illustrating a cross-sectional side view of an exemplary integrated heat spreader power adapter 200 according to an embodiment of the present disclosure. The integrated heat spreader power adapter 200 generally includes components such as an integrated heat spreader housing 250. The integrated heat spreader housing 250 is the combination of a housing and a heat spreader formed by insert molding. The housing part of the integrated heat spreader housing 250 can be made from various materials including, but not limited to electrically insulating materials such as plastics or thermal plastics while the heat spreader part of the integrated heat spreader housing 250 is made of efficient heat conducting materials including, but not limited to, metals such as aluminum or copper or a metal alloy such as stainless steel.

The integrated heat spreader housing 250 includes a top cover shell 216 and a bottom cover shell 220. Each of the top cover shell 216 and the bottom cover shell 220 include a horizontal portion 208 and vertical portions 212. The top cover shell 216 and the bottom cover shell 220 are secured together such as by electronic welding or by a snap-fit, as are known in the art. The integrated heat spreader power adapter 200 further includes an insulator 228. The insulator 228 can be made from various composite polymer materials.

A printed circuit board assembly 232 is disposed within the integrated heat spreader housing 250 and includes various electronic components. The various electronic components are assembled onto the printed circuit board assembly 232 using screws, glue or other assembly mechanisms along with a thermal interface. The various electronic components included on the printed circuit board assembly 232 mainly include, for example a transformer, a rectifier, filter capacitors, a voltage regulator, power switching circuitry, a controller, etc.

The printed circuit board assembly 232 may further include a heat sink and a fan wherein the heat sink absorbs heat from the various electronic components and the fan causes current of the air to carry heat from the heat sink to the outside of the integrated heat spreader housing 250 to lower the inside temperature of the integrated heat spreader power adapter 200.

The external dimensions of the integrated heat spreader power adapter 200 are the same as the conventional power adapter 100 at 95×95×28 mm. The thickness of the horizontal portions 208 for the integrated heat spreader housing 250, however, is only 2.2 mm and the thickness of the vertical portions 212 is only 2.7 mm. Although the thickness of the heat spreader remains the same at 1.2 mm, the horizontal portions 208 are reduced from 2.2 mm to 1.0 mm and the vertical portions 212 are reduced from 2.7 mm to 1.5 mm as compared with the conventional power adapter 100. The insulator 228 has a thickness of 1.25 mm. With these reduced dimensions provided by the integrated heat spreader housing 250, the printed circuit board assembly 232 now has an increased volume or space of 89.1×89.1×23.1 mm or 183,387 mm³. This is an increase of 17.9% compared with the printed circuit board assembly 132 of the conventional heat spreader power adapter 100.

Therefore, with the integrated heat spreader housing 250, the time to assemble the integrated heat spreader power adapter 200 is reduced and the volume or space of the internal cavity to accommodate the printed circuit board assembly 232 is increased. Moreover, the integrated heat spreader housing 250 is formed without the use of an adhesive between the housing and the heat spreader. Furthermore, the integrated heat spreader housing 250 is formed without airgaps between the housing and the heat spreader. Both airgaps and glue affect the heat transfer path for cooling.

With the increased internal cavity of the integrated heat spreader housing 250, larger heat sinks or better airflow could be accommodated within the increased internal cavity which helps to dissipate heat more effectively. Also, the increased internal cavity allows for redesigning the internal layout of circuitry which enables more efficient and higher-power designs.

Moreover, with the increased internal cavity of the integrated heat spreader housing 250, additional components or larger versions of existing components that can handle larger currents or voltage can be provided within the internal cavity which increases the output power of the integrated heat spreader power adapter 200. According to embodiments of the present disclosure, with the increased internal cavity, the integrated heat spreader power adapter 200 increases its output power from 300 W to at least 320 W.

As discussed above, the integrated heat spreader power adapter 200 is capable of providing a high-power output (e.g., 320 W) in a small size housing. As discussed above, the external volume of the integrated heat spreader power adapter 200 is 252,700 mm³. The internal volume of the integrated heat spreader power adapter 200 is 183,387 mm³. In a comparative example, three conventional power adapters (adapter A, adapter B and adapter C) are compared with the integrated heat spreader power adapter 200. The characteristics of the conventional power adapter along with the integrated heat spreader power adapter 200 are provided in Table 1.

TABLE 1

| | Integrated Heat | Power | Power | Power |
|---|---|---|---|---|
| | Spreader Power | Adapter | Adapter | Adapter |
| | Adapter | A | B | C |
| Output Power | 320 W | 300 W | 300 W | 300 W |
| Dimensions | 95 × 95 × 28 mm | 183 × 85 × 35 mm | 200 × 100 × 25 mm | 197 × 88 × 39 mm |
| Volume | 252,700 mm³ | 545,912.5 mm³ | 508,000 mm³ | 684,405.54 mm³ |
| Proportion | 1 | 2.6 | 2.01 | 2.71 |
| Density | 1.26 W/kg | 0.549 W/kg | 0.590 W/kg | 0.438 W/kg |

As illustrated in Table 1, power adapter A has a volume of 545,912.5 mm³, which is more than twice as large as the integrated heat spreader power adapter 200 at a proportion of 2.6 times that of the integrated heat spreader power adapter 200. Power adapter B has a volume of 508,00 mm³, which is slightly more than twice as large as the integrated heat spreader power adapter 200 at a proportion of 2.01 times that of the integrated heat spreader power adapter 200. Power adapter C has a volume of 684,405.54 mm³, which is more than twice as large as the integrated heat spreader power adapter 200 at a proportion of 2.71 times that of the integrated heat spreader power adapter 200.

According to an embodiment of the present disclosure, the integrated heat spreader power adapter 200 provides a power conversion density of 1.26 W/kg. The term “power conversion density” refers to the maximum amount of power a power adapter can deliver divided by the volume of the power adapter. As further described in Table 1, power adapter A provides a power conversion density of 0.549 W/kg. Moreover, power adapter B provides a power conversion density of 0.590 W/kg and power adapter C provides a power conversion density of 0.438 W/kg.

A higher power conversion density indicates that a power adapter can deliver more power within a smaller volume or weight. This can be advantageous in applications where space or weight is limited, such as in portable electronics or compact devices. Conversely, a lower power conversion density means that a power adapter is less efficient at delivering power within a given volume or weight. This may result in larger or heavier power adapters, which could be undesirable in applications where space and weight are critical factors.

Although power adapter A, power adapter B and power adapter C each performs the same function as the lightweight, slim and portable integrated heat spreader power adapter 200, power adapter A, power adapter B and power adapter C are bulky and less efficient at delivering power which make them undesirable in certain situations. With the integrated heat spreader housing 250, the thickness of the conventional housing is reduced but the strength is maintained. The advantages of the integrated heat spreader housing 250 is an effective heat transfer path, an integrated design, sound bounding, improved structural strength to resist environmental and vibrational shock loads, a simplified assembly process and improved durability. As discussed above, the thin design of the integrated heat spreader housing 250 provides for an increased and better utilization of the internal space provided within the integrated heat spreader power adapter 200.

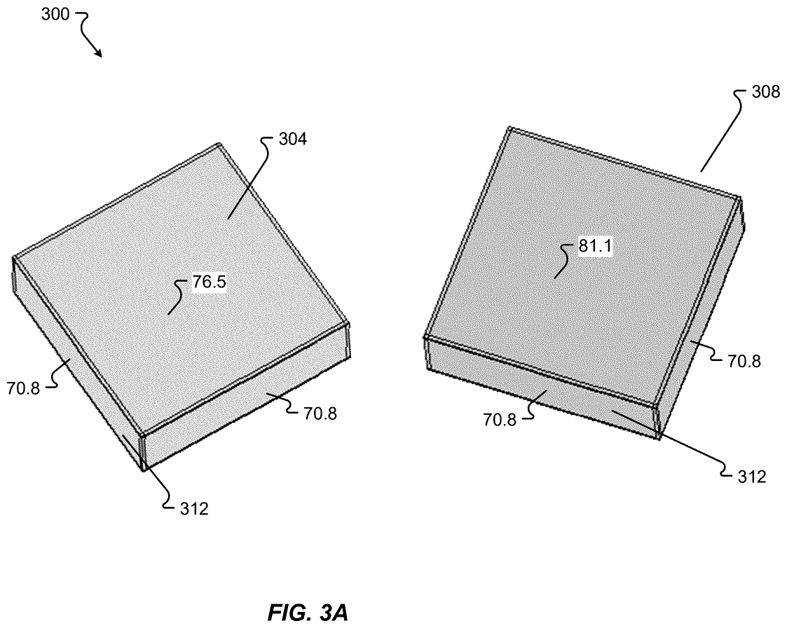

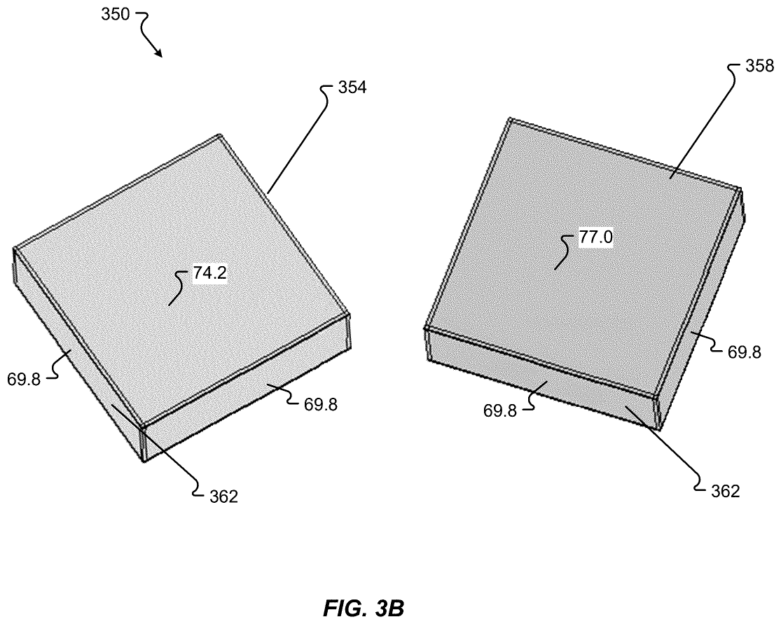

FIG. 3a is a diagram illustrating an isometric view of a conventional heat spreader power adapter 300 after performance of a thermal simulation and FIG. 3b is a diagram illustrating an isometric view of an exemplary integrated heat spreader power adapter 350 according to an embodiment of the present disclosure after performance of a thermal simulation.

The thermal simulation uses the conventional power adapter 300 with an output power of 300 W having external dimensions of 95×95×28 mm. The integrated heat spreader power adapter 350 has the same dimensions and output power. The conventional power adapter 300 and the integrated heat spreader power adapter 350 are placed on a wood table at an ambient temperature of 25° Celsius (C). The efficiency of the conventional power adapter 300 and the integrated heat spreader power adapter 350 are assumed to be 95.5% (14 W power dissipation).

Table 2 below compares the surface temperature differences between the conventional power adapter 300 and the integrated heat spreader power adapter 350.

TABLE 2

| | Conventional | Integrated Heat Spreader |
|---|---|---|
| Location | Power Adapter | Power Adapter |
| Top Surface | 76.5° C. | 74.2° C. |
| Bottom Surface | 81.1° C. | 77.0° C. |
| Side Surfaces | 70.8° C. | 69.8° C. |
| AC input/DC Output Surface | 70.8° C. | 69.8° C. |
| Max Touchable Surface | 56.1° C. | 52.0° C. |
| Temp Rise | | |
| Improvement | N/A | 4.1° C (7.3%) |

As illustrated in FIG. 3a, the conventional power adapter 300 includes a top surface 304, a bottom surface 308 and side surfaces 312. While in operation, the temperature of the top surface 304 is 76.5° C. and the temperature of the bottom surface 308 is 81.1° C. The temperature of the side surfaces 312 is 70.8° C. The temperature of the AC input/DC Output surface is also 70.8° C. The maximum touchable surface temperature rise calculated as the maximum temperature from the bottom surface 308 at 81.1° C. minus the wood table at an ambient temperature of 25° C. which is 56.1° C.

As illustrated in FIG. 3b, the integrated heat spreader power adapter 350 includes a top surface 354, a bottom surface 358 and side surfaces 362. While in operation, the temperature of the top surface 354 is 74.2° C. and the temperature of the bottom surface 358 is 77.0° C. The temperature of the side surfaces 362 is 69.8° C. The temperature of the AC input/DC Output surface is also 69.8° C. The maximum touchable surface temperature rise calculated as the maximum temperature from the bottom surface 358 at 77.0° C. minus the wood table at an ambient temperature of 25° C. which is 52.0° C. There is a 4.1° C. improvement in the maximum surface temperature which represents a 7.3% improvement.

According to embodiments of the present disclosure the integrated heat spreader power adapter 350 provides a groundbreaking solution in the field of heat dissipation of power adapters, which provides better heat dissipation effects, and solves a problem of overheating in the housing of the power adapters. To implement a structure with increased heat dissipation area and enhanced heat dissipation capability, a scheme in which a metal heat spreader is embedded into a plastic housing is used. The metal heat spreader and the plastic housing may be integrally formed, for example by insert molding, to achieve a better heat dissipation capability.

Further, the integrated heat spreader power adapter 350 according to embodiments of the present disclosure has a high thermal conductivity. As compared with conventional plastic housings, since the metal heat spreader having a lower thermal resistance is embedded, heat conduction efficiency is improved, allowing to transfer the heat around from local hot spots, and thereby improving temperature homogeneity over the surface of the integrated heat spreader power adapter 350. In this way, the heat generated by electronic components may be transferred to the outside effectively through the heat dissipation integrated heat spreader housing.

According to embodiments of the present disclosure, the improvements of the skin surface temperature of the integrated heat spreader power adapter 350 results in better heat transfer from the metal heat spreader to the plastic housing and reduces the thickness of the plastic housing.

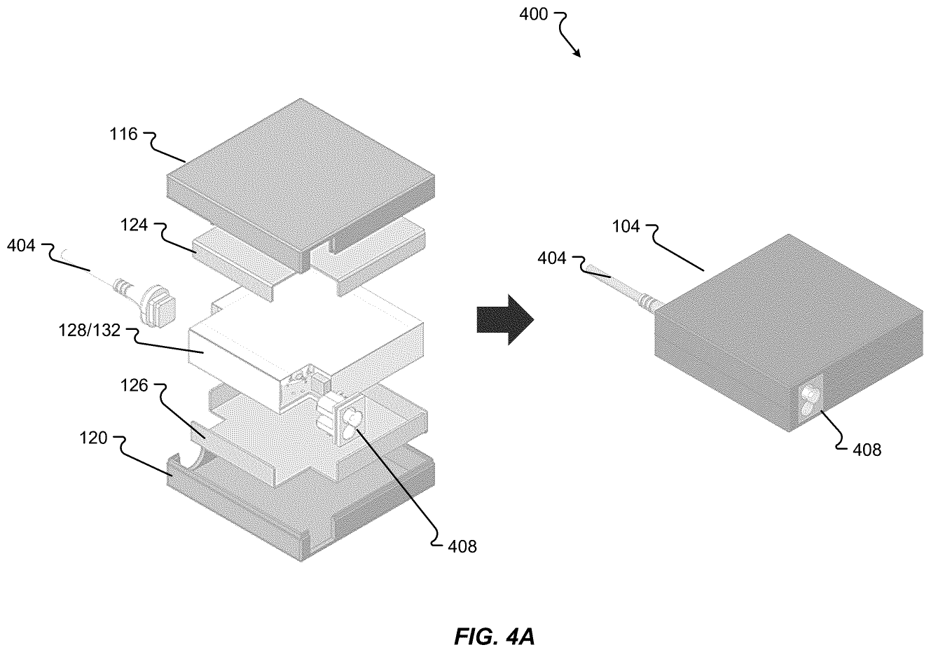

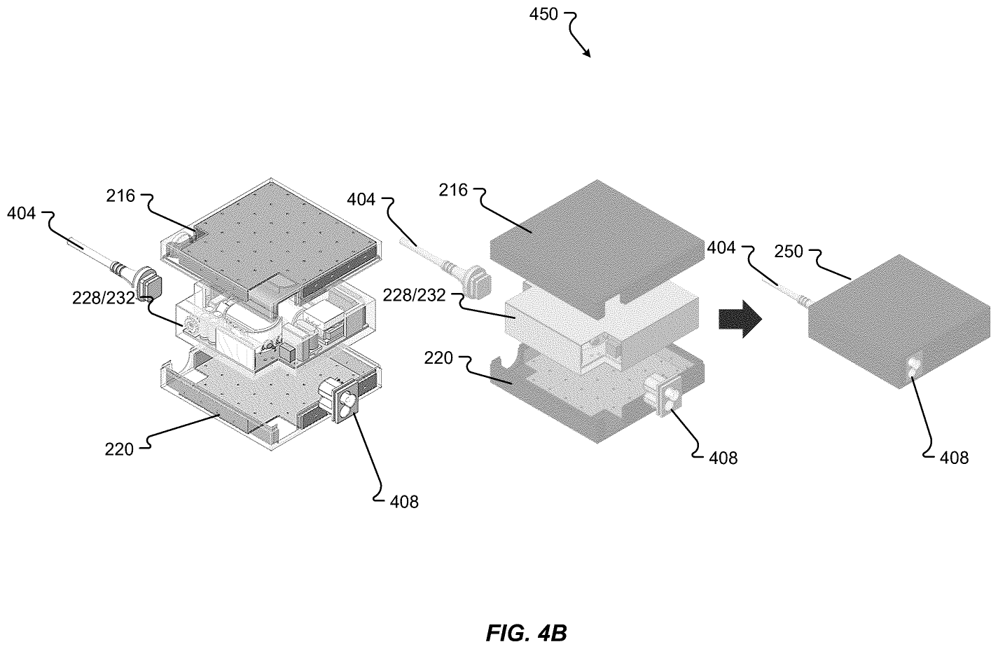

FIG. 4a is a diagram illustrating an isometric view of the construction of a conventional power adapter 400. As illustrated in FIG. 4a, the conventional power adapter 400 includes the top cover shell 116 of the housing 104, the bottom cover shell 120 of the housing 104, the heat spreader separated into two parts, an upper heat spreader 124 and a lower heat spreader 126, and the combination of the insulator and the printed circuit board assembly 128/132. The power adapter 400 further includes a power source input interface 404 and a power source output interface 408. The power source output interface 408 is disposed on a first end of the housing 104 and the power source input interface 404 is disposed on a second end of the housing 104.

The power adapter 400 is constructed by attaching the upper heat spreader 124 and the lower heat spreader 126 to the combination of the insulator and the printed circuit board assembly 128/132 and then attaching the top cover shell 116 and the bottom cover shell 120 together over the upper heat spreader 124, the lower heat spreader 126 and the combination of the insulator and the printed circuit board assembly 128/132. Alternatively, the power adapter 400 is constructed by attaching the upper heat spreader 124 to the inside of the top cover shell 116 and attaching the lower heat spreader 126 to the inside of the bottom cover shell 120.

Afterwards, the top cover shell 116 having the upper heat spreader 124 attached thereto and the bottom cover shell 120 having the lower heat spreader 126 attached thereto are attached to the combination of the insulator and the printed circuit board assembly 128/132.

With this construction of the conventional power adapter 400, airgaps may exist between the top cover shell 116 and the upper heat spreader 124 as well as between the bottom cover shell 120 and the lower heat spreader 126. In addition, an adhesive such as glue may be used to attach the top cover shell 116 to the upper heat spreader 124 and attach the bottom cover shell 120 to the lower heat spreader 126. Both airgaps and glue affect the heat transfer path for cooling. Moreover, the overall thickness of the power adapter 400 is not reduced by combining the components and the inner space of the power adapter 400 does not increase.

FIG. 4b is a diagram illustrating an isometric view of the construction of an exemplary integrated heat spreader power adapter 450 according to an embodiment of the present disclosure. As illustrated in FIG. 4b, the integrated heat spreader power adapter 450 includes the top cover shell 216 of the integrated heat spreader housing 250, the bottom cover shell 220 of the integrated heat spreader housing 250 and the combination of the insulator and the printed circuit board assembly 228/232. The integrated heat spreader power adapter 450 further includes a power source input interface 404 and a power source output interface 408. The power source output interface 408 is disposed on a first end of the integrated heat spreader housing 250 and the power source input interface 404 is disposed on a second end of the integrated heat spreader housing 250.

The integrated heat spreader power adapter 450 is constructed by providing the printed circuit board assembly 228/232 within an internal cavity defined by the top cover shell 216 of the integrated heat spreader housing 250 and the bottom cover shell 220 of the integrated heat spreader housing 250 and then attaching the top cover shell 216 of the integrated heat spreader housing 250 to the bottom cover shell 220 of the integrated heat spreader housing 250. This construction reduces the number of steps to assemble the integrated heat spreader power adapter 450 as compared with the conventional power adapter 400.

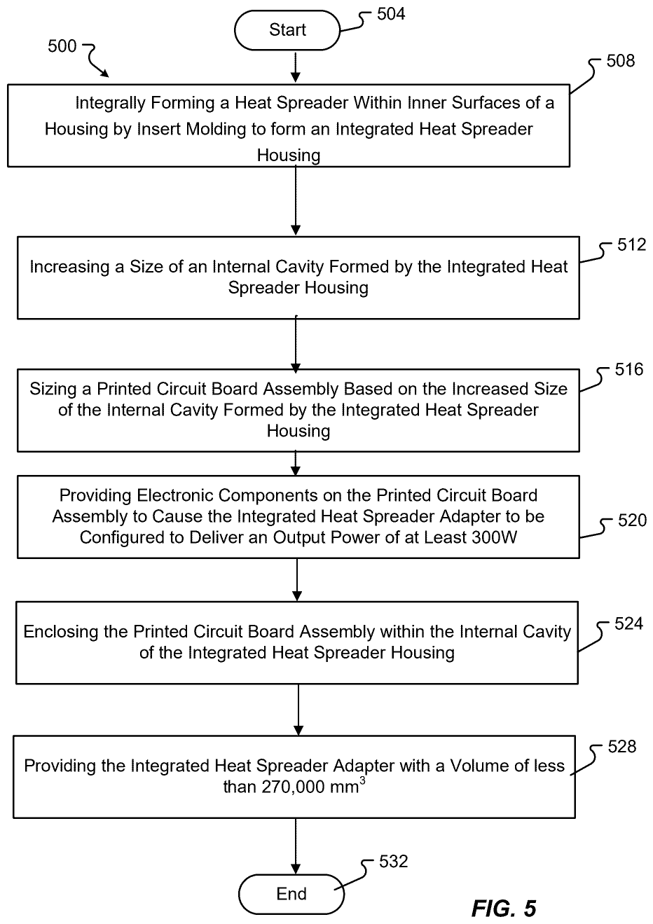

FIG. 5 is a flowchart illustrating an example method 500 for forming an integrated spreader power adapter in accordance with embodiments of the present disclosure. While a general order of the steps of method 500 is shown in FIG. 5, method 500 can include more or fewer steps or can arrange the order of the step differently than those shown in FIG. 5. Further, two or more steps may be combined in one step. Generally, the method 500 starts at a START operation at step 504 and ends with an END operation at step 532. Hereinafter, the method 500 shall be explained with reference to the systems, components, modules, applications, etc. described in conjunction with FIGS. 1-4 and 6.

Method 500 begins at step 504 and proceeds to step 508, where a heat spreader is integrally formed within inner surfaces of a housing by insert molding to form an integrated heat spreader housing. After the heat spreader is integrally formed at step 508, method 500 proceeds to step 512, wherein a size of an internal cavity formed by the integrated heat spreader housing is increased. The size of the internal cavity formed by the integrated heat spreader housing is increased as compared with the size of an internal cavity of a power adapter formed by a nonintegrated heat spreader housing as discussed above in FIG. 1.

After a size of an internal cavity formed by the integrated heat spreader housing has been increased at step 512, method 500 proceeds to step 516 wherein a printed circuit board assembly is sized based on the increased size of the internal cavity formed by the integrated heat spreader housing. After sizing a printed circuit board assembly based on the increased area of the internal cavity formed by the integrated heat spreader housing at step 516, method 500 proceeds to step 520, wherein electronic components are provided on the printed circuit board assembly to cause the integrated heat spreader power adapter to be configured to deliver an output power of at least 320 W. After providing electronic components on the printed circuit board assembly to cause the integrated heat spreader power adapter to be configured to deliver an output power of at least 320 W at step 520, method 500 proceeds to step 524, wherein the printed circuit board assembly is enclosed within the internal cavity of the integrated heat spreader housing.

After providing the printed circuit board assembly within the internal cavity of the integrated heat spreader housing at step 524, method 500 proceeds to step 528, wherein the heat spreader power adapter is provided to have a volume of less than 270,00 mm³. After providing the heat spreader power adapter to have a volume of less than 270,00 mm³ at step 528, method 500 ends with the END operation at step 532. Any of the steps, functions, and operations discussed herein can be performed continuously and automatically.

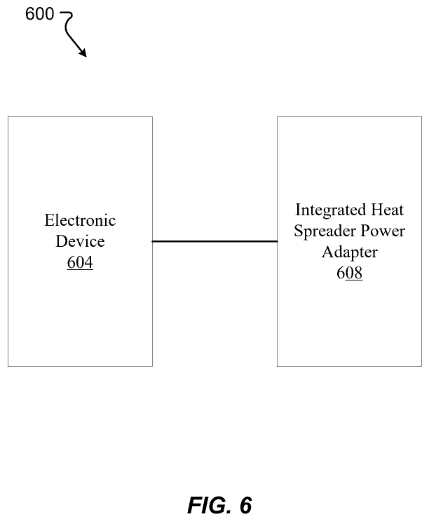

FIG. 6 is a block diagram of an electronic device system 600 according to an embodiment of the present disclosure. The electronic device system 600 shown in the figure includes an integrated heat spreader power adapter 604 and an electronic device 608. The integrated heat spreader power adapter 604 is configured to charge the electronic device 608. For a specific implementation of the integrated heat spreader power adapter 604, refer to related descriptions in the foregoing embodiments. Details are not described in this embodiment of this disclosure again. The electronic device 608 may be a smartphone, a laptop computer, a wearable electronic device (for example, a smartwatch), a tablet computer, an augmented reality device, a virtual reality device, a vehicle-mounted device, or the like. This is not specifically limited to the embodiments of the present disclosure.

The integrated heat spreader power adapter 604 supports a wired charging function, a wireless charging function, or both a wired charging function and a wireless charging function. The integrated heat spreader power adapter 604 may charge one or more electronic devices 608 at the same time. When the integrated heat spreader power adapter 604 charges a plurality of electronic devices 608 at the same time, the plurality of electronic devices 608 may be electronic devices of a same type or different types. When the integrated heat spreader power adapter 604 performs wired charging on the electronic device 608, the electronic device system 600 further includes a connection cable. A first end of the connection cable is connected to a charging port of the electronic device 608, and a second end of the connection cable is connected to an output interface of the integrated heat spreader power adapter 604.

During actual application, the integrated heat spreader power adapter 604 may be directly connected to a power supply by using a pin or may be connected to the power supply by using the connection cable. This is not specifically limited to the embodiments of the present disclosure.

Described above is an integrated heat spreader power adapter which may be used for powering and/or charging consumer electronic devices. However, the techniques described herein are not limited to power adapters for consumer electronic devices. Some embodiments relate to an integrated heat spreader power adapter for other electronic devices, such as servers or other devices in a data center, which may benefit from a reduction in size of the power electronics. Other non-limiting examples of applications include power electronics.

Various aspects of the apparatus, method and techniques described herein may be used alone, in combination, or in a variety of arrangements not specifically discussed in the embodiments of the present disclosure described in the foregoing description and is therefore not limited in its application to the details and arrangement of components set forth in the foregoing description or illustrated in the drawings. For example, aspects described in one embodiment of the present disclosure may be combined in any manner with aspects described in other embodiments of the present disclosure.

The foregoing embodiments of the present disclosure are only intended for describing the technical solutions of this disclosure other than limiting this disclosure. Although this disclosure is described in detail with reference to the foregoing embodiments, a person of ordinary skill in the art should understand that they may still make modifications to the technical solutions described in the foregoing embodiments or make equivalent replacements to some technical features thereof, without departing from the scope of the technical solutions of embodiments of this disclosure.

Furthermore, while the embodiments illustrated herein show the various components in a single device, certain components can be in one or multiple devices. Thus, it should be appreciated, that the components can be combined into one or more devices.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire, and fiber optics, and may take the form of acoustic or light waves, such as those generated during radio-wave and infra-red data communications.

While the flowcharts have been discussed and illustrated in relation to a particular sequence of events, it should be appreciated that changes, additions, and omissions to this sequence can occur without materially affecting the operation of the disclosed embodiments, configuration, and aspects.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

A number of variations and modifications of the disclosure can be used. It would be possible to provide for some features of the disclosure without providing others.

The present disclosure, in various embodiments, configurations, and aspects, includes components, methods, processes, systems and/or apparatus substantially as depicted and described herein, including various embodiments, subcombinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving case, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

What is claimed is:

1. A method for manufacturing an integrated heat spreader power adapter, comprising:
integrally forming a heat spreader within inner surfaces of a housing by insert molding to form an integrated heat spreader housing;
increasing a size of an internal cavity formed by the integrated heat spreader housing;
sizing a printed circuit board assembly based on the increased size of the internal cavity formed by the integrated heat spreader housing;
providing electronic components on the printed circuit board assembly to cause the integrated heat spreader power adapter to be configured to deliver an output power of a least 320 watts; and
enclosing the printed circuit board assembly within the internal cavity of the integrated heat spreader housing,
wherein the integrated heat spreader power adapter has a volume of less than 270,000 mm³.

2. The method of claim 1, wherein the heat spreader of the integrated heat spreader housing comprises a metal.

3. The method of claim 1, wherein the housing of the integrated heat spreader housing comprises a plastic material.

4. The method of claim 1, wherein a power conversion density of the integrated heat spreader power adapter is 1.1 W/Kg or higher.

5. The method of claim 1, further comprising providing an insulator between the integrated heat spreader housing and the printed circuit board assembly.

6. The method of claim 1, further comprising increasing the size of the internal cavity with the integrated heat spreader housing formed by insert molding by at least 15% as compared with a nonintegrated heat spreader housing.

7. The method of claim 1, further comprising decreasing a thickness of a length of the housing of the integrated heat spreader power adapter formed by insert molding by at least 40% as compared with a nonintegrated heat spreader housing.

8. The method of claim 1, further comprising decreasing a thickness of a height of the housing of the integrated heat spreader power adapter formed by insert molding by at least 40% as compared with a power adapter formed by a nonintegrated heat spreader housing.

9. The method of claim 1, further comprising lowering an external surface temperature of the integrated heat spreader power adapter formed with the integrated heat spreader housing as compared with a power adapter formed by a nonintegrated heat spreader housing.

10. The method of claim 9, wherein during operation of the integrated heat spreader power adapter, an external surface temperature of a top portion of the integrated heat spreader power adapter is below 75° C.

11. The method of claim 9, wherein during operation of the integrated heat spreader power adapter, an external surface temperature of a bottom portion of the integrated heat spreader power adapter is below 78° C.

12. The method of claim 9, wherein during operation of the integrated heat spreader power adapter, an external surface temperature of side portions of the power adapter is below 70° C.

13. An integrated heat spreader power adapter, comprising:
an integrated heat spreader housing formed by insert molding of a housing and a heat spreader;
an internal cavity formed by the integrated heat spreader housing,
wherein the integrated heat spreading housing increases a size of the internal cavity; and
a printed circuit board assembly provided within the increased size of the internal cavity formed by the integrated heat spreader housing,
wherein the printed circuit board is sized based on the increased size of the internal cavity,
wherein the printed circuit board includes electronic components provided thereon to cause the integrated heat spreader power adapter to be configured to deliver an output power of at least 320 watts, and
wherein the integrated heat spreader power adapter has a volume of less than 270,000 mm³.

14. The integrated heat spreader power adapter of claim 13, further comprising an insulator provided between the integrated heat spreader housing and the printed circuit board assembly.

15. The integrated heat spreader power adapter of claim 13, wherein the heat spreader comprises a metal and the housing comprises a plastic material.

16. The integrated heat spreader power adapter of claim 13, wherein a power conversion density of the integrated heat spreader power adapter is 1.2 W/Kg or higher.

17. The integrated heat spreader power adapter of claim 13, wherein during operation of the integrated heat spreader power adapter, an external surface temperature of a top portion of the integrated heat spreader power adapter is below 75° C.

18. An electronic device system, comprising:
an integrated heat spreader power adapter including:
an integrated heat spreader housing formed by insert molding of a housing and a heat spreader;
an internal cavity formed by the integrated heat spreader housing,
wherein the integrated heat spreading housing increases a size of the internal cavity; and
a printed circuit board assembly provided within the increased size of the internal cavity formed by the integrated heat spreader housing,
wherein the printed circuit board is sized based on the increased size of the internal cavity,
wherein the printed circuit board includes electronic components provided thereon to cause the integrated heat spreader power adapter to be configured to deliver an output power of at least 320 watts, and
wherein the integrated heat spreader power adapter has a volume of less than 270,000 mm³; and
an electronic device,
wherein the integrated heat spreader power adapter is coupled to charge the electronic device.

19. The electronic device system of claim 18, further comprising an insulator provided between the integrated heat spreader housing and the printed circuit board assembly.

20. The electronic device system of claim 18, wherein the heat spreader comprises a metal and the housing comprises a plastic material.
